(19) United States
(12) Patent Application Publication
(10) Pub. No.: US 2011/0316142 A1
(43) Pub. Date: Dec. 29, 2011

(54) SEMICONDUCTOR MODULE WITH RESIN-MOLDED PACKAGE OF HEAT SPREADER AND POWER SEMICONDUCTOR CHIP

(75) Inventors: Chikage NORITAKE, Ama-gun (JP); Naoki HIRAIWA, Toyokawa-shi (JP); Tsuyoshi ARAI, Nagoya (JP)

(73) Assignee: DENSO CORPORATION, Kariya-city (JP)

(21) Appl. No.: 13/166,101

(22) Filed: Jun. 22, 2011

(30) Foreign Application Priority Data
Jun. 23, 2010 (JP) 2010-143058

(51) Int. Cl. H01L 23/34

(52) U.S. Cl. 257/713; 257/E23.08

(57) ABSTRACT

A semiconductor module is provided which includes a resin molded package which is made by a resinous mold assembly. The resin molded package is clamped by covers through a fastener to make the semiconductor module. The resinous mold assembly has formed therein a coolant path that is a portion of a coolant passage through which a coolant flows to coal a semiconductor chip embedded in the resin molded package. The resinous mold assembly is made up of a first mold and a second mold. The first mold has the semiconductor chip, heat spreaders, and electric terminals embedded therein. The second mold is wrapped around an outer periphery of the first mold. The second mold is made of resin which is lower in softening temperature than that of the first mold, thereby facilitating ease of removing the first mold from the resin molded package for reusing the resin molded package.

### CROSS REFERENCE TO RELATED DOCUMENT

The present application claims the benefit of priority of Japanese Patent Application No. 2010-143058 filed on Jun. 23, 2010, the disclosure of which is incorporated herein by reference.

### BACKGROUND OF THE INVENTION

1. Technical Field

The present invention relates generally to a semiconductor module which is equipped with a resin-molded package with a power semiconductor chip and a heat spreader working to spread heat from the power semiconductor chip and which may be of a 1-in-1 structure into which a single power semiconductor chip(s) such as an IGBT or a power MOSFET for use as either of an upper arm (i.e., a high side device) or a lower arm (i.e., a low side device) of an inverter is resin-molded, or a 2-in-1 structure into which two power semiconductor power chips for use as the upper and lower arms, respectively, are resin-molded.

2. Background Art

One of typical semiconductor modules is equipped with a resin mold package in which a semiconductor chip(s) and a heat spreader(s) serving to dissipate heat, as generated by the semiconductor chip, are disposed. As the resin material for such mold, thermosetting resin such as epoxy resin is usually used in order to improve thermal endurance of the package.

The thermosetting resin is, however, difficult to remove after being hardened. Therefore, when any part of the thermosetting resin has broken down, the expensive power semiconductor chip must also be scrapped.

In recent years, a demand for reusing the semiconductor chips has been increasing with increasing awareness of environmental issues.

Japanese Patent First Publication No. 2006-165534 teaches a semiconductor module which consists of stacked resin molded packages and coolant paths. In each of the resin molded packages, a power semiconductor chip(s) and heat spreaders are embedded. When one of the resin molded packages has become defective, the semiconductor module may be disassembled to remove only the defective package and reused by replacing it with a new one.

However, when the resin molded package is removed from the semiconductor module, the surfaces of the packages are susceptible to damage. It is undesirable to replace such a resin molded package itself. Such damage causes deterioration of quality of the mold and results in need for the package to be scrapped even though the power semiconductor chip which is embedded in the package operates properly.

### SUMMARY

It is therefore an object to provide an improved structure of a semiconductor module designed to permit a power semiconductor chip to be reused when a resin mold is damaged.

According to one aspect of an embodiment, there is provided a semiconductor module which may be employed with an inverter for an electric motor.

The semiconductor module comprises: (a) a resin molded package; (b) a first cover disposed on a first surface of the resin molded package; (c) a second cover disposed on a second surface of the resin molded package; and (d) a fastener which fastens the first and second covers to hold the resin molded package. The resin molded package includes a resinous mold assembly. The resinous mold assembly has embedded therein a power semiconductor chip which has a first and a second surfaces opposed to each other, a first heat spreader disposed in connection with the first surface of the power semiconductor chip, a second heat spreader disposed in connection with the second surface of the power semiconductor chip, and electric terminals connected with the power semiconductor chip and an external device(s) such as a capacitor(s). The resinous mold assembly also has formed therein a coolant path through which a coolant flows to cool the power semiconductor chip. The first cover is disposed on a first surface of the resin molded package. The resinous mold assembly of the resin molded package includes a first mold and a second mold. The first mold has the power semiconductor chip, the first and second heat spreaders, and the electric terminals embedded therein, such that a portion of each of the electric terminals is exposed outside the resinous mold assembly, and a surface of each of the first and second spreaders which is located opposite the power semiconductor chip is also exposed outside the resinous mold assembly. The second mold covers an outer periphery of the first mold. The first mold is made of a first resin material. The second mold is made of a second resin material which is lower in softening temperature than the first resin material.

The power semiconductor chip, the first and second heat spreaders, and the electric terminals are encapsulated or embedded in the first mold in order to improve thermal endurance thereof. The second mold surrounds or is wrapped around the outer periphery of the first mold. This structure of the semiconductor module enables the resin molded package to be replaced with a new one if it is broken down, thus permitting the semiconductor module to be reused. If only the second mold is damaged, for example, scratched, removal of the second mold may be achieved by heating the resin molded package to soften the second mold. The remaining parts of the resin molded package may be reassembled along with a mint second mold to rebuild the resin molded package. In other words, the semiconductor module may be recovered without discarding, for example, the power semiconductor chip.

In the preferred mode of the embodiment, the first resin material is a thermosetting resin, while the second resin material is a thermoplastic resin.

For example, the thermosetting resin is one of epoxy, phenol, and silicone resin. The thermoplastic resin is one of polyphenylene sulfide (PPS), polybutylene terephthalate, nylon, polyethylene, and polypropylene resin.

The semiconductor module may also include a rubber member such a rubber film which is secured to an interface between the first and second molds to create a hermetical seal therebetween, thereby keep coolant from entering between the first and second molds.

According to another aspect of an embodiment, there is provided a semiconductor module which comprises: (a) a plurality of resin molded packages each of which is made by a resinous mold assembly and which are laid to overlap each other as a package stack; (b) a first cover disposed on a first surface of the package stack; (c) a second cover disposed on a second surfaced of the package stack; and (d) a fastener which fastens the first and second covers to hold the package stack. The resinous mold assembly has embedded therein a power semiconductor chip which has a first and a second surfaces opposed to each other, a first heat spreader disposed in connection with the first surface of the power semiconductor chip, a second heat spreader disposed in connection with the second surface of the power semiconductor chip, and electric terminals connected electrically with the power semiconductor chip. The resinous mold assembly also has formed therein a coolant path that is a portion of a coolant passage through which a coolant flows to cool the semiconductor chips.

The resinous mold assembly of each of the resin molded packages includes a first mold and a second mold. The first mold has the power semiconductor chip, the first and second heat spreaders, and the electric terminals embedded therein, such that a portion of each of the electric terminals is exposed outside the resinous mold assembly, and a surface of each of the first and second spreaders which is located opposite the power semiconductor chip is also exposed outside the resinous mold assembly. The second mold covers an outer periphery of the first mold. The first mold is made of a first resin material. The second mold is made of a second resin material which is lower in softening temperature than the first resin material.

The semiconductor chip, the first and second heat spreaders, and the electric terminals of each of the semiconductor modules are encapsulated or embedded in the first mold in order to improve thermal endurance. The second mold surrounds or is wrapped around the outer periphery of the first mold. This structure of the semiconductor module enables any of the resin molded packages to be replaced with a new one if it is broken down, thus permitting the semiconductor module to be reused. If only the second mold of one of the semiconductor modules is damaged, for example, scratched, removal of the second mold may be achieved by heating the resinous mold assembly to soften the second mold. The remaining parts of the resin molded package may be reassembled along with a mint second mold to rebuild the resin molded package. In other words, the semiconductor module may be recovered without discarding, for example, the power semiconductor chip.

In the preferred mode of the invention, the first resin material is a thermosetting resin, while the second resin material is a thermoplastic resin.

For example, the thermosetting resin is one of epoxy, phenol, and silicone resin. The thermoplastic resin is one of polyphenylene sulfide, polybutylene terephthalate, nylon, polyethylene, and polypropylene resin.

The semiconductor module may also include a rubber member such a rubber film is secured to an interface between the first and second molds of each of the semiconductor modules to create a hermetical seal therebetween, and thereby keep coolant from entering between the first and second molds.

### BRIEF DESCRIPTION OF THE DRAWINGS

The present invention will be understood more fully from the detailed description given hereinbelow and from the accompanying drawings of the preferred embodiments of the invention, which, however, should not be taken to limit the invention to the specific embodiments but are for the purpose of explanation and understanding only.

In the drawings:

FIG. 1 is a vertical sectional view which shows a semiconductor module according to the first embodiment;

FIG. 2(a) is a plane view which show one of resin molded packages built in the semiconductor module of FIG. 1;

FIG. 2(b) is a cross sectional view, as taken along the line A-A′ of FIG. 2(a);]

FIG. 2(c) is a cross sectional view, as taken along the line B-B′ of FIG. 2(a);

FIGS. 3(a), 3(b), 3(c), 3(d), and 3(e) are cross sectional views which demonstrate a sequence of steps of producing the resin molded package, as illustrated in FIGS. 2(a) to 2(c);

FIGS. 4(a), 4(b), and 4(c) are cross sectional views which demonstrate a sequence of steps of assembling the semiconductor module, as illustrated in FIG. 1;

FIGS. 5(a), 5(b), and 5(c) are cross sectional views which demonstrate a sequence of steps of disassembling the semiconductor module, as illustrated in FIG. 1;

FIGS. 6(a), 6(b), and 6(c) are cross sectional views which demonstrate a sequence of steps of removing a power car and rebuilding the resin molded package, as illustrated in FIGS. 2(a) to 2(c); and

FIG. 7 is a transverse sectional view which illustrates a resin molded package according to the second embodiment.

### DESCRIPTION OF THE PREFERRED EMBODIMENTS

Referring to the drawings, wherein like reference numbers refer to like parts in several views, there is shown a semiconductor module 1 with a cooling mechanism according to the first embodiment.

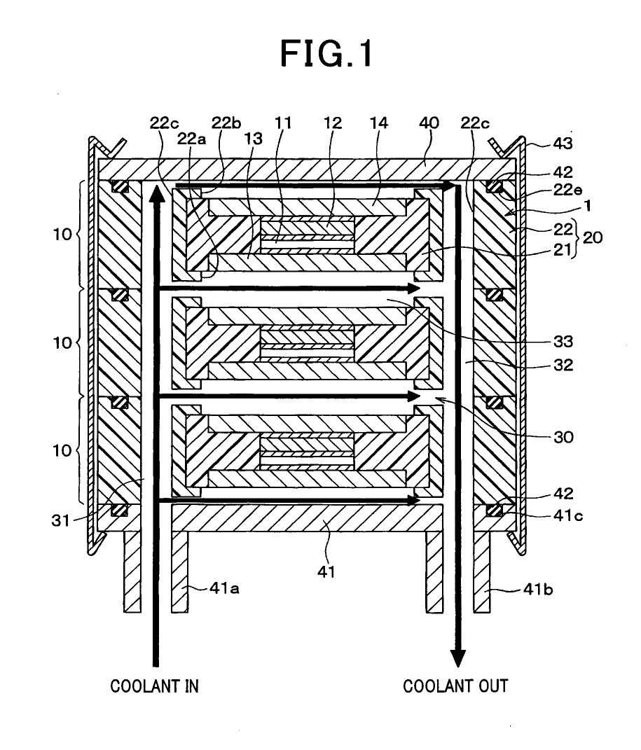

FIG. 1 is a vertical cross sectional view which illustrates the semiconductor module 1. The semiconductor module 1 includes a stack of resin-molded packages 10. Each of the resin molded packages 10 is equipped with a power semiconductor chip 11. The resin molded packages 10 are substantially identical in structure with each other, and the following discussion will be referred to only one of the resin molded packages 10 for the simplicity of disclosure.

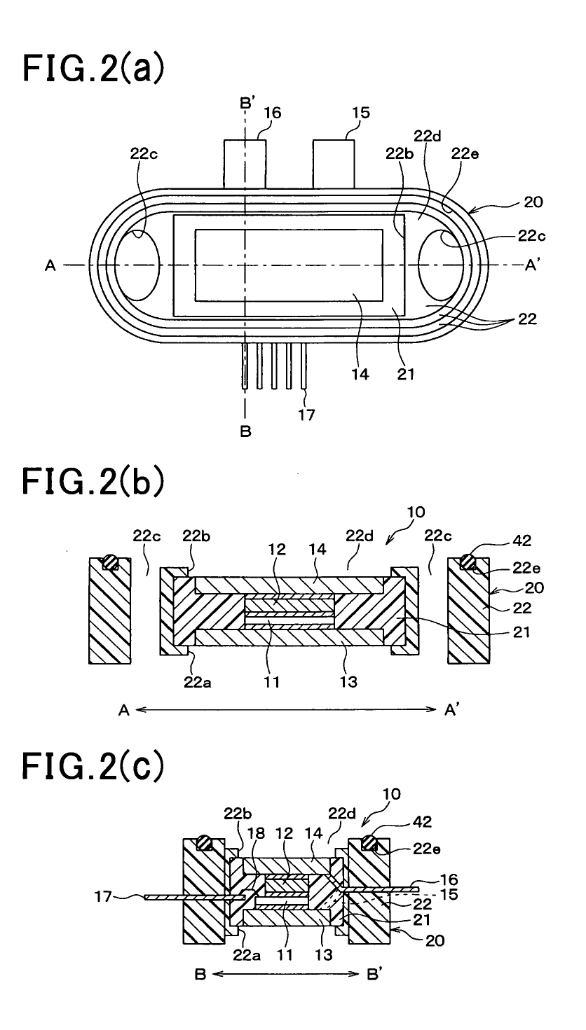

FIGS. 2(a) to 2(c) illustrate the structure of the resin molded package 10. FIG. 2(a) is a front view of the resin molded package 10. FIG. 2(b) is a cross sectional view, as taken along the line A-A′ of FIG. 2(a). FIG. 2(c) is a cross sectional view, as taken along the line B-B′ of FIG. 2(c).

The resin molded package 10 also includes a metal block 12, heat spreaders 13 and 14, a positive electric terminal 15, a negative electric terminal 16, and signal terminals 17. The power semiconductor chip 11, the metal block 12, the heat spreaders 13 and 14, the positive electric terminal 15, the negative electric terminal 16, and the signal terminals 17 are molded by resin into a single resinous mold assembly 20 as the resin molded package 10. The resin molded package 10 is of a 1-in-1 structure equipped with the single power semiconductor chip 11, but may alternatively be designed to have two or more power semiconductor chips 11.

In this embodiment, the power semiconductor chip 11 has mounted thereon a semiconductor power device such as an IGBT which is of a vertical type in which electric current flows in a thickness-wise direction thereof. The power semiconductor chip 11 has some types of pads disposed on a first and a second surface thereof. Specifically, the pads are formed on the first surface of the power semiconductor chip 11 in electrical connection with a gate and an emitter of the IGBT, while the pad is formed on the entire area of the second surface of the power semiconductor chip 11 in electrical connection with a collector of the IGBT.

The power semiconductor chip 11 is of a horizontal type in which the current flows in a lateral direction of a base thereof.

The metal block 12 is made of a metallic material such as copper or aluminum which is high in thermal conductivity. The metal block 12 is glued or soldered mechanically and electrically to the pad which is formed on the first surface of the power semiconductor chip 11 and connected to the emitter of the IGBT. The metal block 12 is disposed on the first surface of the power semiconductor chip 11 to secure an interval between the first surface of the power semiconductor chip 11 and the heat spreader 14.

Each of the heat spreaders 13 and 14 spreads heat generated by the power semiconductor chip 11. The heat spreader 13 is also joined mechanically and electrically to the pad on the second surface of the power semiconductor chip 11 and additionally serves as an electric lead connected with the collector of the IGBT. The heat spreader 14 is secured mechanically and electrically to the metal block 12 and additionally serves as an electric lead connected with the emitter of the IGBT. Each of the heat spreaders 13 and 14 is made of metal such as copper that is high in thermal conductivity and formed by a square metallic plate of a given thickness. The surface of each of the heat spreaders 13 and 14 which is farther away from the power semiconductor chip 11 is exposed from the resinous mold assembly 20 to coolant, as will be described later in detail. This surface of each of the heat spreaders 13 and 14 also has disposed thereon an insulating member (not shown) for use in insulating the heat spreaders 13 and 14 from the coolant to avoid the leakage of electric current from the heat spreaders 13 and 14 to the coolant. The positive electric terminal 15 is formed integrally with the heat spreader 13 as a part thereof or soldered or welded thereto, so that it is connected electrically with the pad which is affixed to the second surface of the power semiconductor chip 11 and leads to the collector of the IGBT. The end of the positive electric terminal 15 is exposed from the resinous mold assembly 20 for electric connection with an external device.

The negative electric terminal 16 is formed integrally with the heat spreader 14 as a part thereof or soldered or welded thereto, so that it is connected electrically with the pad which is affixed to the first surface of the power semiconductor chip 11 and leads to the emitter of the IGBT. One of ends the negative electric terminal 16 is exposed from the resinous mold assembly 20 for electric connection with an external device.

The signal terminals 17 are used to monitor the current flowing through the lead wire connecting with the gate of the power semiconductor chip 11 and the semiconductor power device itself and also to monitor the temperature of the power semiconductor chip 11. The signal terminals 17 are electrically joined at ends thereof to the pads formed on the first surface of the power semiconductor chip 11 through bonding wires 18 and also exposed at other ends thereof outside the resinous mold assembly 20 for electrical connections with an external device. The spacing between the first surface of the power semiconductor chip 11 and the heat spreader 14 is, as described above, created by the metal block 12, thus ensuring the electrical connections of the power semiconductor chip 11 to the signal terminals 17 without physical and electrical interferences of the bonding wires 18 with the heat spreader 14.

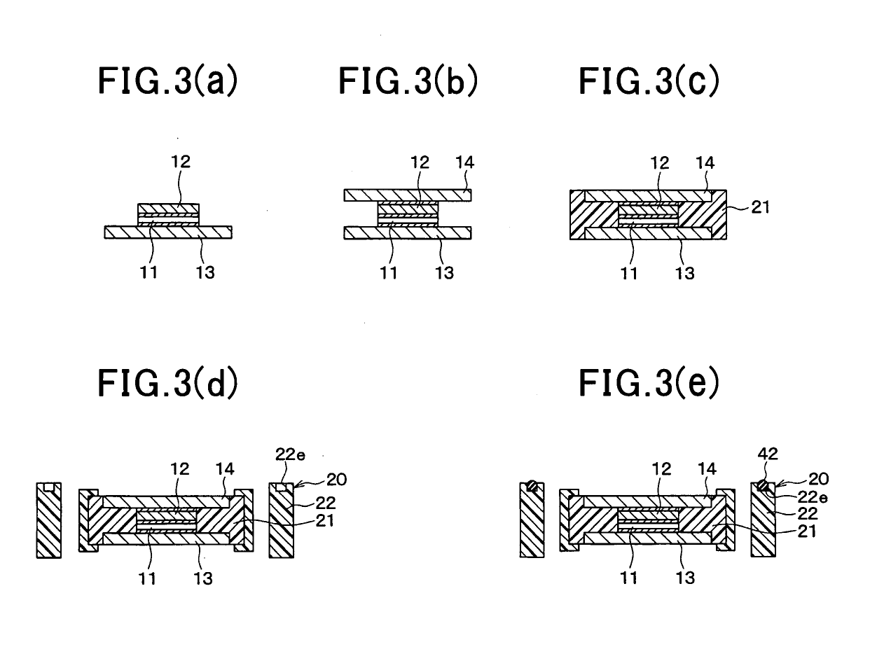

The formation of the resinous mold assembly 20 is made in the following steps. Components, i.e., the power semiconductor chip 11 and a metal terminal are assembled on the heat spreaders 13 with the negative electric terminal 16 by a solder (FIG. 3(a)). Then, signal pads on the first surface of the semiconductor chip 11 are connected with signal terminals by wires 18. Then, the heat spreader 14 with the positive electric terminal 15 is connected by solder (FIG. 3(b)). A first mold is then formed by a transfer forming machine. The resinous mold assembly 20 is made up of a thermosetting resin-made body 21 (i.e., the first mold) and a thermoplastic resin-made shell 22 (i.e., a second mold). The thermosetting resin-made body 21 has the above components embedded therein. The thermoplastic resin-made shell 22 functions as a frame to surround or wall the periphery of the thermosetting resin-made body 21 (FIG. 3(c)).

The thermosetting resin-made body 21 is made of, for example, epoxy, phenol, or silicone resin and wraps or insulates the components of the resin molded package 10. The thermosetting resin-made body 21 is so shaped as to have the ends of the positive electric terminal 15, the negative electric terminal 16, and the signal terminals 17 extend outside it and the major surfaces of the heat spreaders 13 and 14 exposed outside it. Of the parts of the resinous mold assembly 20, just only the thermosetting resin-made body 21 insulates and waterproofs the components of the resin molded package 10. The thermosetting resin-made body 21 is of a rectangular shape and has two long side surfaces from one of which the positive electric terminal 15 and the negative electric terminal 16 extend and from the other of which the control terminals 16 extend. The thermosetting resin-made body 21 in which the components of the resin molded package 10 are disposed is usually referred to as a power card. The power card is used as a resin molded package equipped with no coolant path.

The thermoplastic resin-made shell 22 is made of, for example, polyphenylene sulfide, polybutylene terephthalate, nylon, polyethylene, or polypropylene resin and covers the periphery of the thermosetting resin-made body 21 so as to have the ends of the positive electric terminal 15, the negative electric terminal 16, and the signal terminals 17 and the surfaces of the heat spreaders 13 and 14 exposed outside it. Specifically, the thermoplastic resin-made shell 22 has formed therein rectangular windows 22a and 22b from which the surfaces of the heat spreaders 13 and 14 are exposed outside the resin molded package 10.

The thermoplastic resin-made shell 22, as illustrated in FIG. 1, defines a portion of a coolant path 30 working as a cooling system through which coolant or refrigerant flows to cool the power semiconductor chip 11. Specifically, the thermoplastic resin-made shell 22 is made of an enclosed oval plate with long side surfaces extending in parallel to the long side surfaces of thermosetting resin-made body 21. The thermoplastic resin-made shell 22 has oval holes 22c and recesses 22d formed therein. The holes 22c are located in portions of the thermoplastic resin-made shell 22 which lie, as clearly illustrated in FIG. 2(a), outside the opposed ends of the thermosetting resin-made body 21 and define the portion of the coolant path 30. The recesses 22d are formed in the opposed major surfaces of the thermoplastic resin-made shell 22. The recesses 22d also define, as can be seen from FIG. 1, a portion of the coolant path 30. Specifically, when the resin molded packages 10 are, as illustrated in FIG. 1, stacked to overlap each other, the holes 22c and the recesses 22d of the thermoplastic resin-made blocks 22 complete the coolant path 30.

The thermoplastic resin-made shell 22 has formed in the peripheral edge thereof a seal mount groove 22e which extends around the recess 22d and in which an O-ring 42, as illustrated in FIGS. 1, 2(b), and 2(c), is fit. When the resin molded packages 10 are, as illustrated in FIG. 1, stacked to overlap each other, the O-rings 42 of each of the resin molded packages 10 will be placed in direct abutment with the adjacent resin molded package 10 to create a hermetical seal therebetween which avoids the leakage of cooling water flowing through the coolant path 30 to outside the resinous molds 20.

The semiconductor module 1 also includes, as illustrated in FIG. 1, an upper cover 40, a lower cover 41, and clampers 43.

The upper cover 40 and the lower cover 41 are, as can be seen from FIG. 1, disposed on opposed ends of a stack of the resin molded package 10. The cover 40 is made of a plate contoured to conform with the contour of the resinous mold assembly 20 of each of the resin molded packages 10. When the cover 40 is placed on the end of the stack of the resin molded packages 10, an air gap is created between the second surface of the cover 40 and the recess 22d of an uppermost one of the resin molded packages 10. The lower cover 41 is made of a plate contoured to conform with the contour of the resinous mold assembly 20 of each of the resin molded package 10 and equipped with two pipes 41a and 41b. The pipes 41a and 41b extend substantially perpendicular to the lower cover 41 and communicate with the holes 22c of the resin molded packages 10 which are aligned to define the coolant path 30. The is pipe 41a serves as a coolant inlet, while the pipe 41b serves as a coolant outlet. The lower cover 41 also has formed therein a seal mount groove 41c in which the O-ring 42 is fit.

The O-rings 42 are fit in the seal mount holes 22e of the resin molded packages 10 and the seal mount holes 41c of the lower cover 41 to develop hermetical seals between every adjacent two of the resin molded packages 10 and between the resin molded packages 10 and the upper and lower covers 40 and 41.

The clampers 43 function as fastener to firmly join the upper and lower covers 40 and 41 and a stack of the resin molded packages 10 in which the O-rings 42 are disposed in the grooves 22e and 41c to complete the semiconductor module 1. Specifically, each of the clampers 43, as can be seen in FIG. 1, clamps the upper and lower covers 40 and 41 to hold the assembly of the upper and lower cover 40 and 41 and the stack of the resin molded packages 10 tightly, thereby completing the coolant path 30 within the semiconductor module 1. Such an assembly will also be referred to as a module assembly below. The clampers 43 are detachable for disassembling the upper and lower covers 40 and 41 and the resin molded packages 10. Each of the clampers 43 has hooks formed at ends thereof. The interval between the hooks is smaller than the thickness of the module assembly of the upper and lower covers 40 and 41 and the stack of the resin molded packages 10 so that the hooks of each of the clampers 43 may nip the upper and lower covers 40 and 41 elastically. Each of the clampers 43 may alternatively be designed to hold the module assembly using screws instead of the hooks.

The use of the O-rings 42 in the semiconductor module 1 constructed, as described above, creates the hermetic seals among the resin molded packages 10, the upper cover 40, and the lower cover 41, thus avoiding the leakage of the cooling water from the coolant path 30 and ensuring a required degree of cooling the semiconductor chips 11 of the resin molded packages 10. Specifically, the pipe 41a and one of the two holes 22c of the respective resin molded packages 10, as illustrated in FIG. 1, define an inlet flow path 31, while the pipe 41b and the other hole 22c of the respectively resin molded packages 10 define an outlet flow path 32. The recess 22c formed in the surface of each of the resin molded packages 10 define a branch path 33. The cooling water enters the pipe 41a, flows through the inlet flow path 31, diverges into the branch paths 33, and then discharges from the outlet flow path 32 through the pipe 41b. The cooling water flows in direct contact with the heat spreaders 13 and 14 within the branch paths 33 and cools them, so that the heat, as generated by the semiconductor chips 11, will be absorbed by the cooling water.

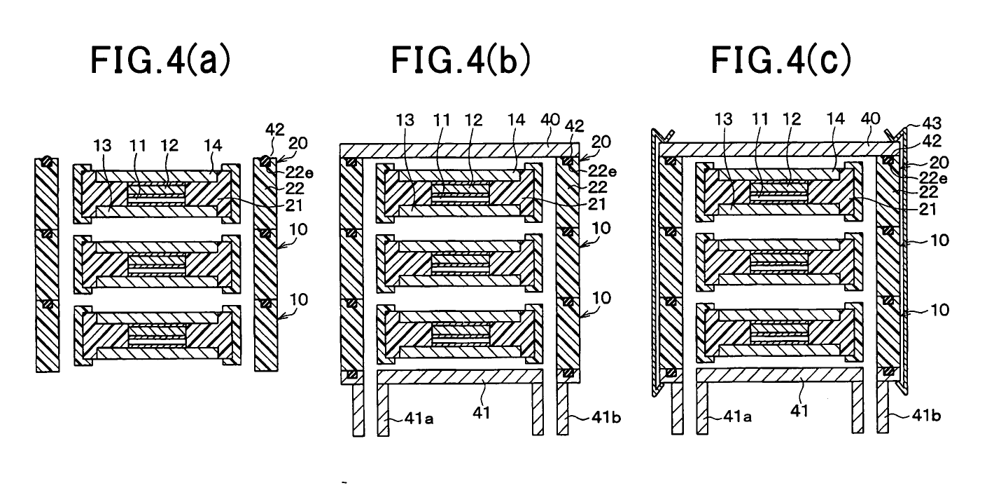

The production method of the semiconductor module 1 will be described below with reference to FIGS. 3(a) to 4(c).

Step in FIG. 3(a)

A, lead frame is prepared in which the positive electric terminal 15, the negative electric terminal 16, and the signal terminals 17 are disposed in place. The lead frame is put on the surface of the heat spreader 13. The positive electric terminal 15 is soldered to the surface of the heat spreader 13. The power semiconductor chip 11 on which the semiconductor power device such an IGBT and/or an FWD is fabricated is soldered to the surface of the heat spreader 13. Afterwards, the pads formed on the surface of the power semiconductor chip 11 which connect with, for example, the gate of the semiconductor power device are joined to the signal terminals 17 through the bonding wires 18. The metal block 12 is soldered to the surface of the power semiconductor chip 11.

Step in FIG. 3(b)

Solder is put on the surfaces of the metal block 12 and the negative electric terminal 16. The heat spreader 14 is placed on the solder and then joined to the metal block 12 and the negative electric terminal 16.

Step in FIG. 3(c)

The components of the resin molded package 10 which are connected together in the above manner is put in, for example, a transfer mold of a transfer molding machine. Thermosetting resin such as epoxy resin is injected into the transfer mold to form the thermosetting resin-made body 21, thereby making the power card, as described above. The power card has the outside major surfaces of the heat spreaders 13 and 14 exposed to the outside, however, may be shaped to enclose the heat spreaders 13 and 14 fully, after which opposed major surfaces of the power card can be ground or removed to expose the outside major surfaces of the heat spreaders 13 and 14 to the outside.

If the outside major surfaces of the heat spreaders 13 and 14 exposed to outside the thermosetting resin-made body 21 are electrically insulated, it may result in electrical communication between the heat spreaders 13 and 14 of every adjacent two of the resin molded packages 10 when assembled as the semiconductor module 1. In order to avoid this problem, insulators such as insulating films are preferably affixed to the outside major surfaces of the heat spreaders 13 and 14 before or after the thermosetting resin-made body 21 is formed.

Step in FIG. 3(d)

The power card formed by the thermosetting resin-made body 21 into which the above components are resin-molded is put in another mold. Thermoplastic resin such as polyphenylene sulfide is injected into the mold to form thermoplastic resin-made shell 22, thereby completing the resin molded package 10. The lead frames of the heat spreaders 13 and 14 may be removed in this step

Step in FIG. 3(e)

The O-rings 42 are fitted in the grooves 22e of the thermoplastic resin-made shells 22 of the resin molded packages 10.

Step in FIG. 4(a)

A plurality of the resin molded packages 10 each of which has been produced in the steps of FIGS. 3(a) to 3(e) are prepared. For example, the three resin molded packages 10 are prepared and placed to overlap each other to make an package stack.

Step in FIG. 4(b)

The upper and lower covers 40 and 41 are prepared. The O-ring 42 is fitted in the seal mount groove 41c of the lower cover 41. The upper cover 40 is place on one of opposed ends of the package stack, while the lower cover 41 is placed on the other end of the package stack. Such an assembly will also be referred to as a module assembly below.

Step in FIG. 4(c)

The package stack and the upper and lower cover 40 and 41 which are assembled in the above steps are retained tightly by the clamps 43 to complete the semiconductor module 1, as illustrated in FIG. 1.

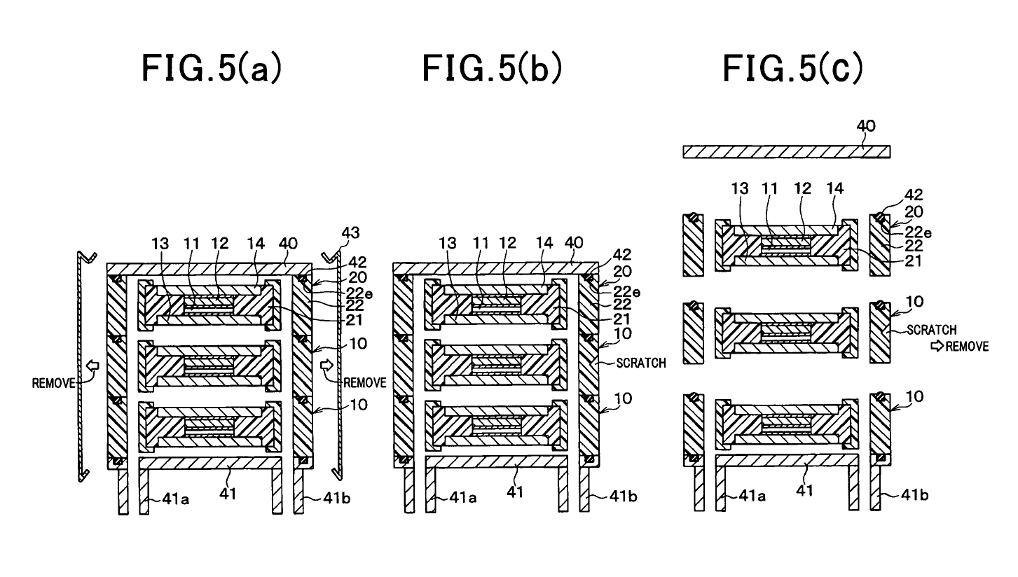

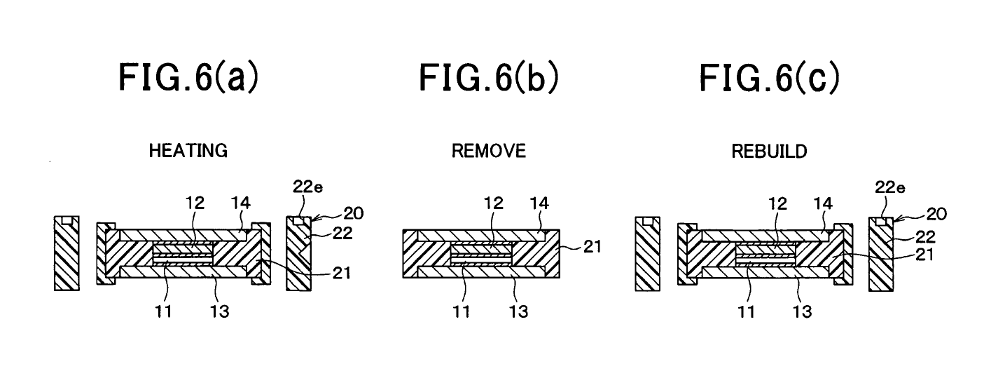

If one of the resin molded packages 10 of the semiconductor module 1 has been damaged or broken during the production or use thereof, it may be replaced in the manner demonstrated in FIGS. 5(a) to 6(c).

Step in FIG. 5(a)

The clampers 43 are removed from the module assembly of the upper and lower covers 40 and 41 and the package stack. For instance, the removal of the clamper 43 is achieved by deforming the hooks thereof elastically. In the case where the clamper 43 is fixed to the module assembly using screws, the removal of the clamper 43 is achieved by loosening the screws.

Steps in FIGS. 5(b) and 5(c)

If the resinous mold, assembly 20 of one of the resin molded packages 10 is, as illustrated in FIG. 5(b), damaged or scratched, an operator identifies it, disassembles the upper cover 40, the resin molded packages 10, and the lower cover 41, and removes the scratched resin molded package 10.

Step in FIG. 6(a)

The damaged resin molded package 10 is put in a thermal processing machine such as a heating furnace and then heated at a temperature higher than or equal to a glass transition temperature (i.e., a softening temperature) of the thermoplastic resin-made shell 22 and lower than a glass transition temperature of the thermosetting resin-made body 21.

In the case where the thermoplastic resin-made shell 22 is made of polyphenylene sulfide, and the thermosetting resin-made body 21 is made of epoxy resin, the damaged resin molded package 10 is heated at 120° C. which is higher than or equal to the glass transition temperature of the poiyphenylene sulfide and lower than the glass transition temperature of the epoxy resin. The glass transition temperature usually depends upon amounts of resin and filler. A desired value of the glass transmission temperature of the thermoplastic resin-made shell 22 or the thermosetting resin-made body 21 is, therefore, determined by selecting the amounts of resin and filler thereof.

Step in FIG. 6(b)

The damaged resin molded package 10 continues to be heated in the thermal processing machine, so that only the thermoplastic resin-made body 22 is softened and permitted to be removed from the resin molded package 10 to leave only the power card (i.e., thermosetting resin-made body 21) as it is. Note that the thermoplastic resin is in a state intermediate between solid and liquid at the above temperature, so that it does not disappear naturally, but may be removed easily from the resin molded package 10 by pushing or pulling the thermoplastic resin-made body 22,

Step in FIG. 6(c)

The power card made by the thermosetting resin-made body 21 by which the components are encapsulated is put in the same mold as described above in FIG. 3(d). Thermoplastic resin is injected into the mold to form the thermoplastic resin-made shell 22 again, thereby rebuilding the resin molded package 10.

The rebuilt resin molded package 10 and the above described remaining resin molded packages 10 are stacked in the same manner as described in FIG. 4(a). The upper and lower covers 40 and 41 are placed on the opposed ends of the package stack and the nipped by the clampers 43 to rebuilding the semiconductor module 1.

This enables portions of the resin molded package 10 other than the thermoplastic resin-made shell 22 to be reused without disposing the components of the resin molded package 10 such as the power semiconductor chip 11, the heat spreaders 13 and 14, etc.

As apparent from the above discussion, the components (e.g., the power semiconductor chip 11, etc.) of the resin molded package 10 is encapsulated by the thermosetting resin-made body 21 to ensure required heat resistance properties thereof. Additionally, the periphery of the thermosetting resin-made body 21 is covered by the thermoplastic resin-made shell 22. The thermoplastic resin-made shell 22 defines a portion of the coolant path 30. The coolant path 30 is completed when the resin molded packages 10 are assembled as the semiconductor module 1 and works as a cooling mechanism to dissipate the heat from the resin molded packages 10.

If one of the resin molded packages 10 is broken, the structure of the semiconductor module 1 permits it to be replaced with another one, thereby enabling the semiconductor module 1 to be reused. If only the thermoplastic resin-made shell 22 is damaged, it may be thermally softened and removed from the resin molded package 10 to leave the thermosetting resin-made body 21 (i.e., the power card) as it is. The thermosetting resin-made body 12 may be used again to rebuild the resin molded package 10. This eliminates the need for discarding the components of the resin molded package 10 such as the power semiconductor chip 11, etc.

If any one of the resin molded packages 10 is broken, and the surface of another of the resin molded packages 10 is damaged or scratched while the semiconductor module 1 is being disassembled, the structure of the resin molded package 10 enables the components thereof such as the power semiconductor chip 11, etc. to be reused for resources.

The semiconductor module 1 according to the second embodiment will be described below which is designed to keep coolant from entering between the thermosetting resin-made body and thermoplastic resin-made shell 22. Basic structural arrangements of the semiconductor module 1 are substantially identical with those in the first embodiment. The same reference numbers as employed in the first embodiment will refer to the same parts, and explanation thereof in detail will be omitted here.

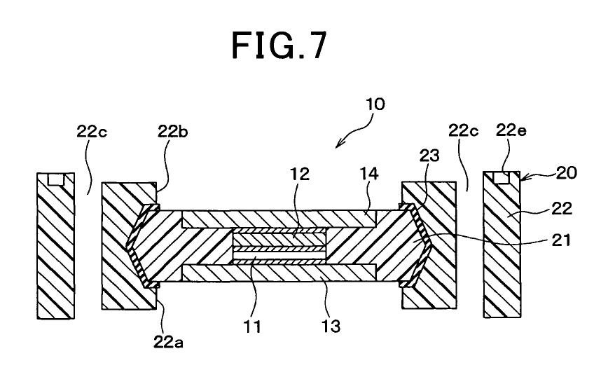

FIG. 7 is a cross sectional view which illustrates one of resin molded packages 10 making up the semiconductor modules 1 of this embodiment. The resin molded packages 10 of the semiconductor module 1 are, like in the first embodiment, identical in structure with each other, and only one of them will be described below for the brevity of disclosure.

The resin molded package 10 includes a rubber member 23 which is made of a rubber sheet or film and is insert-molded to be located between the thermosetting resin-made body 21 and the thermoplastic resin-made shell 22. The installation of the rubber member 23 in the resin molded package 10 is made by insert-molding the components of the resin molded package 10 such as the semiconductor chip 1, etc., with resin to form the thermosetting resin-made body 21, wrapping the rubber member 23 around the periphery of thermosetting resin-made body 21, and then insert-molding the thermosetting resin-made body 21 with resin to form the thermoplastic resin-made shell 21. The surface of the rubber member 23 is pressed by pressure arising from shrinkage of the thermoplastic resin-made shell 22 after being molded, so that the rubber member 23 will be interposed between the outer circumference of the thermosetting resin-made body 21 and the inner circumference of the thermoplastic resin-made shell 22 hermetically without any clearances therebetween.

The rubber member 23, therefore, serves to hold the coolant from intruding into the interface between the thermosetting resin-made body 21 and the thermoplastic resin-made shell 22.

While the present invention has been disclosed in terms of the preferred embodiments in order to facilitate better understanding thereof, it should be appreciated that the invention can be embodied in various ways without departing from the principle of the invention. Therefore, the invention should be understood to include all possible embodiments and modifications to the shown embodiments which can be embodied without departing from the principle of the invention as set forth in the appended claims.

For example, thermosetting resin-made body 21 and the thermoplastic resin-made shell 22 may be both made of either of thermosetting resin or thermoplastic resin. Specifically, the shell 22 is made of resin which is lower in softening temperature than that of the body 21, thereby enabling the shell 22 to be softened and removed from the resin molded package 10 in the same manner, as described above. It is however, advisable that the body 21 be made of thermosetting resin in terms of the heat resistance, while the shell 22 be made of thermoplastic resin in order to permit it to be softened at low temperatures.

The rubber member 23 of the second embodiment is affixed to the entire interface between the thermosetting resin-made body 21 and the thermoplastic resin-made shell 22, but may alternatively be secured to at least a portion of contact between the thermosetting resin-made body 21 and the thermoplastic resin-made shell 22 which is exposed to the coolant flowing in the coolant path 30.

The semiconductor module 1 has been described as being used in the inverter for driving the three-phase electric motor, but may alternatively be used with other types of electrical devices.

The coolant flowing through the coolant path 30 may be water or another type of cooling medium.

The semiconductor module 1 may be made to include the only one resin molded package 10 which is retained tightly between the upper and lower covers 40 and 41 through the clampers 43.

What is claimed is:

1. A semiconductor module comprising:
a resin molded package which includes a resinous mold assembly, the resinous mold assembly having embedded therein a power semiconductor chip which has a first and a second surfaces opposed to each other, a first heat spreader disposed in connection with the first surface of the power semiconductor chip, a second heat spreader disposed in connection with the second surface of the power semiconductor chip, and electric terminals connected with the power semiconductor chip, the resinous mold assembly also having formed therein a coolant path through which a coolant flows to cool the power semiconductor chip;
a first cover disposed on a first surface of the resin molded package;
a second cover disposed on a second surface of the resin molded package; and
a fastener which fastens the first and second covers to hold the resin molded package,
wherein the resinous mold assembly of the resin molded package includes a first mold and a second mold, the first mold having the power semiconductor chip, the first and second heat spreaders, and the electric terminals embedded therein, such that a portion of each of the electric terminals is exposed outside the resinous mold assembly, and a surface of each of the first and second spreaders which is located opposite the power semiconductor chip is also exposed outside the resinous mold assembly, the second mold covering an outer periphery of the first mold, the first mold being made of a first resin material, the second mold being made of a second resin material which is lower in softening temperature than the first resin material.

2. A semiconductor module as set forth in claim 1, wherein the first resin material is a thermosetting resin, while the second resin material is a thermoplastic resin.

3. A semiconductor module as set forth in claim 2, wherein the thermosetting resin is one of epoxy, phenol, and silicone resin.

4. A semiconductor module as set forth in claim 2, wherein the thermoplastic resin is one of polyphenylene sulfide, polybutylene terephthalate, nylon, polyethylene, and polypropylene.

5. A semiconductor module as set forth in claim 1, further comprising a rubber member secured to an interface between the first and second molds to create a hermetical seal therebetween.

6. A semiconductor module comprising:
a plurality of resin molded packages each of which is made by a resinous mold assembly, the resin molded packages being laid to overlap each other as a package stack, the resinous mold assembly having embedded therein a power semiconductor chip which has a first and a second surfaces opposed to each other, a first heat spreader disposed in connection with the first surface of the power semiconductor chip, a second heat spreader disposed in connection with the second surface of the power semiconductor chip, and electric terminals connected electrically with the power semiconductor chip, the resinous mold assembly also having formed therein a coolant path that is a portion of a coolant passage through which a coolant flows to cool the semiconductor chips;
a first cover disposed on a first surface of the package stack;
a second cover disposed on a second surfaced of the package stack; and
a fastener which fastens the first and second covers to hold the package stack,
wherein the resinous mold assembly of each of the resin molded packages includes a first mold and a second mold, the first mold having the power semiconductor chip, the first and second heat spreaders, and the electric terminals embedded therein, such that a portion of each of the electric terminals is exposed outside the resinous mold assembly, and a surface of each of the first and second spreaders which is located opposite the power semiconductor chip is also exposed outside the resinous mold assembly, the second mold covering an outer periphery of the first mold, the first mold being made of a first resin material, the second mold being made of a second resin material which is lower in softening temperature than the first resin material.

7. A semiconductor module as set forth in claim 6, wherein the first resin material is a thermosetting resin, while the second resin material is a thermoplastic resin.

8. A semiconductor module as set forth in claim 7, wherein the thermosetting resin is one of epoxy, phenol, and silicone resin.

9. A semiconductor module as set forth in claim 7, wherein the thermoplastic resin is one of polyphenylene sulfide, polybutylene terephthalate, nylon, polyethylene, and polypropylene.

10. A semiconductor module as set forth in claim 6, further comprising a rubber member which is secured to an interface between the first and second molds of each of the resin molded packages to create a hermetical seal therebetween.
